(19) United States
(12) Patent Application Publication
(10) Pub. No.: US 2019/0107881 A1
(43) Pub. Date: Apr. 11, 2019

(54) METHOD AND APPARATUS FOR REDUCING IDLE POWER CONSUMPTION FROM PROGRAMMABLE LOGIC DEVICE BASED ACCELERATORS

(71) Applicant: Intel Corporation, Santa Clara, CA (US)

(72) Inventor: George S. POWLEY, Northborough, MA (US)

(21) Appl. No.: 16/216,827

(22) Filed: Dec. 11, 2018

(51) Int. Cl. G06F 1/3237; H03K 19/177; G06F 1/3228; G06F 1/3293

(52) U.S. Cl. CPC G06F 1/3237; G06F 1/3293; G06F 1/3228; H03K 19/17708

(57) ABSTRACT

A method for managing power on a programmable logic device (PLD) based accelerator unit in a computer system includes determining when the PLD based accelerator unit is in an idle state. A PLD in the PLD based accelerator unit is reconfigured from a fully operational state to a low power state in response to determining the accelerator unit is in the idle state.

### FIELD

Embodiments of the present disclosure relate to programmable logic device based accelerators. More specifically, embodiments of the present disclosure relate to a method and apparatus for reducing idle power consumption from programmable logic device based accelerators.

### BACKGROUND

Hardware acceleration implements computing tasks in hardware to decrease latency and increase throughput. Hardware acceleration utilizes computer hardware to perform functions in a more efficient manner than by using software running on a general-purpose processor. Any function that can be computed, can be calculated using software run on a generic processor, custom-made hardware, or a combination of both. A function can be computed faster in application-specific hardware designed or programmed to compute the operation than specified in software and performed on a general-purpose processor.

Traditionally, general-purpose processors were sequential in that they executed instructions one at a time, and were designed to run general purpose algorithms controlled by instruction fetch which involved moving temporary results to and from a register file. Hardware accelerators improve the execution of a specific algorithm by allowing for greater concurrency, having specific data paths for its temporary variables, and reducing the overhead of instruction control in the fetch-decode execute cycle. Hardware accelerators are suitable for any computation-intensive algorithm which is executed frequently. Depending upon the granularity, hardware acceleration can vary from a small functional unit, to a large functional block.

Hardware acceleration have been applied to applications such as computer graphics, analog and digital signal processing, sound processing, computer networking, cryptography, artificial intelligence, multilinear algebra, physics simulation, data compression, and other computing tasks.

### BRIEF DESCRIPTION OF THE DRAWINGS

The features and advantages of embodiments of the present disclosure are illustrated by way of example and are not intended to limit the scope of the embodiments of the present disclosure to the particular embodiments shown.

FIG. 1 illustrates a block diagram of a computer system implementing an accelerator unit according to an exemplary embodiment of the present disclosure.

FIG. 2 illustrates a portion of a programmable logic device that may be used on an accelerator unit according to an exemplary embodiment of the present disclosure.

FIG. 3 is a flow chart illustrating a method for managing power on an accelerator unit according to an exemplary embodiment of the present disclosure.

FIG. 4 is a flow chart illustrating a method for monitoring demand/usage of a programmable logic device based accelerator unit according to an exemplary embodiment of the present disclosure.

FIG. 5 is a flow chart illustrating a method for managing idle power of a programmable logic device based accelerator unit according to an exemplary embodiment of the present disclosure.

FIG. 6 is a flow chart illustrating a method for generating program files for configuring a programmable logic device based accelerator system according to an exemplary embodiment of the present disclosure.

FIG. 7 illustrates the power requirement of an accelerator unit during various operational stages when utilizing the power management methodology according to an exemplary embodiment of the present disclosure.

### DETAILED DESCRIPTION

In the following description, for purposes of explanation, specific nomenclature is set forth to provide a thorough understanding of embodiments of the present disclosure. It will be apparent to one skilled in the art that specific details in the description may not be required to practice the embodiments of the present disclosure. In other instances, well-known circuits, devices, procedures, and programs are shown in block diagram form to avoid obscuring embodiments of the present disclosure unnecessarily.

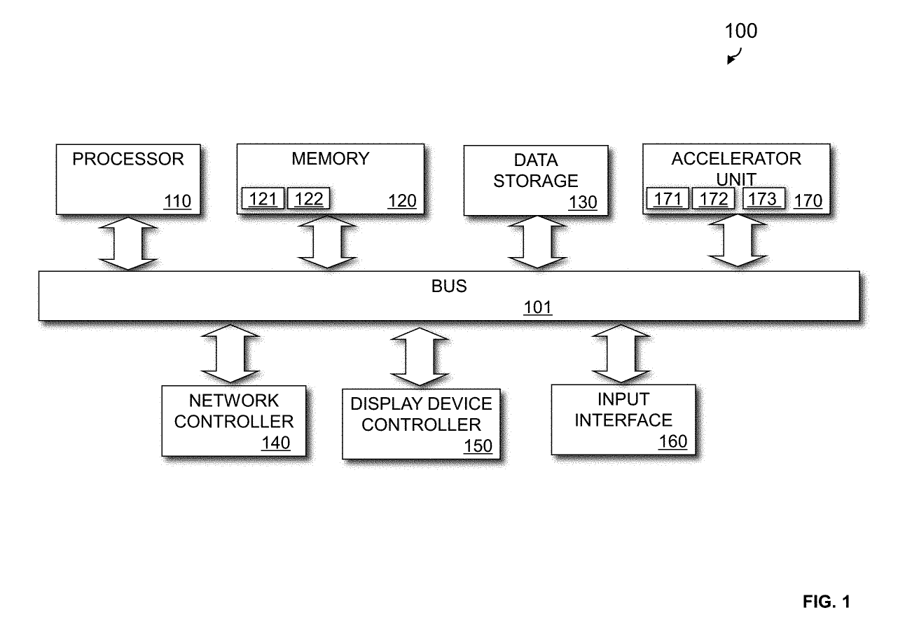

FIG. 1 illustrates a block diagram of a computer system 100 implementing an accelerator unit 170 according to an exemplary embodiment of the present disclosure. The computer system 100 includes a processor 110 that process data signals. The processor 110 is coupled to a bus 101 or other switch fabric that transmits data signals between processor 110 and other components in the computer system 100. The computer system 100 includes a memory 120. The memory 120 may store instructions and code represented by data signals that may be executed by the processor 110. A data storage device 130 is also coupled to the bus 101.

A network controller 140 is coupled to the bus 101. The network controller 140 may link the computer system 100 to a network of computers (not shown) and supports communication among the machines. A display device controller 150 is coupled to the bus 101. The display device controller 150 allows coupling of a display device (not shown) to the computer system 100 and acts as an interface between the display device and the computer system 100. An input interface 160 is coupled to the bus 101. The input interface 160 allows coupling of an input device (not shown) to the computer system 100 and transmits data signals from the input device to the computer system 100.

An accelerator unit 170 is coupled to the bus 101. According to an embodiment of the present disclosure, the accelerator unit 170 includes a programmable logic device 171, data storage 172, and a memory 173. It should be appreciated that the programmable logic device 171 may be reconfigured during runtime to support a variety of features. The accelerator unit 170 may be used to support the workload of an application running on the computer system 100. For example, the accelerator unit 170 may perform hardware acceleration by utilizing the programmable logic device 171 to perform functions that may otherwise be assigned to the processor 110.

An application 121 is stored in memory 120 and is executed by the processor 110. The application 121 may utilize the processor 110 to perform one or more functions. The application 121 may also request that the accelerator unit 170 or that the programmable logic device 171 on the accelerator unit 170 be used in the alternative to or in combination with the processor 110 to perform the one or more functions.

An accelerator unit driver 122 is stored in memory and executed by the processor 110. The accelerator unit driver 122 manages the operation of the accelerator unit 170. According to an embodiment of the present disclosure, the accelerator unit driver 122 schedules the usage of the accelerator unit 170 to perform functions for the application, and manages the configuration and reconfiguration of the programmable logic device 171 to support performance and reduce power consumption during idle states.

According to an embodiment of the present disclosure, the programmable logic device 171 may include an internal processor that executes an application. In this embodiment, the computer system 100 may include only the accelerator unit 170, and the accelerator unit 170 may utilize components on the programmable logic device 171, other than the internal processor, to support the workload of the application running on the internal processor.

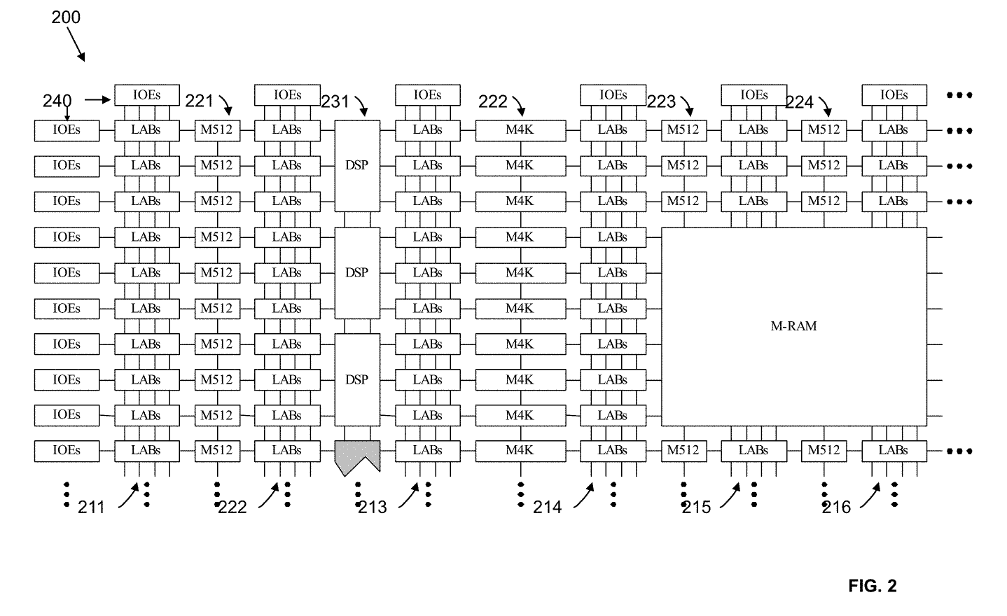

FIG. 2 illustrates a portion of a programmable logic device 200 according to an embodiment of the present disclosure. According to an exemplary embodiment of the present disclosure, the programmable logic device 200 may be used to implement the programmable logic device 171 in the accelerator unit 170 illustrated in FIG. 1. The programmable logic device 200 is a field programmable gate array (FPGA) and is implemented on a die. The programmable logic device 200 includes a plurality of logic-array blocks (LABs). According to an embodiment of the present disclosure, the programmable logic device 200 may be implemented on a single integrated circuit. Each LAB may be formed from a plurality of logic blocks, carry chains, LAB control signals, look up table (LUT) chain, and register chain connection lines. A logic block is a small unit of logic providing efficient implementation of user logic functions. A logic block includes one or more combinational cells, where each combinational cell has a single output, and registers. According to one embodiment of the present disclosure, the logic block may operate similarly to a logic element (LE), such as those found in the Stratix device manufactured by Intel Corporation, or a combinational logic block (CLB) such as those found in Virtex devices manufactured by Xilinx Inc. In this embodiment, the logic block may include a four input LUT with a configurable register. According to an embodiment of the present disclosure, the logic block may be implemented by an adaptive logic module (ALM), such as those found in Stratix devices. LABs are grouped into rows and columns across the programmable logic device 200. Columns of LABs are shown as 211-216. It should be appreciated that the logic block may include additional or alternate components. It should be appreciated that a carry chain may be implemented with the resources of one or more LABs in the programmable logic device 200.

The programmable logic device 200 includes memory blocks. The memory blocks may be, for example, dual port random access memory (RAM) blocks that provide dedicated true dual-port, simple dual-port, or single port memory up to various bits wide at up to various frequencies. The memory blocks may be grouped into columns across the device in between selected LABs or located individually or in pairs within the programmable logic device 200. Columns of memory blocks are shown as 221-224.

The programmable logic device 200 includes digital signal processing (DSP) blocks. The DSP blocks may be used to implement multipliers of various configurations with add or subtract features. The DSP blocks include shift registers, multipliers, adders, and accumulators. The DSP blocks may be grouped into columns across the programmable logic device 200 and are shown as 231.

The programmable logic device 200 includes a plurality of input/output elements (IOEs) 240. Each IOE feeds an IO pin (not shown) on the programmable logic device 200. The IOEs 240 are located at the end of LAB rows and columns around the periphery of the programmable logic device 200. Each IOE may include a bidirectional IO buffer and a plurality of registers for registering input, output, and output-enable signals.

The programmable logic device 200 may include routing resources such as LAB local interconnect lines, row interconnect lines (“H-type wires”), and column interconnect lines (“V-type wires”) (not shown) to route signals between components on the target device. It should be appreciated that the programmable logic device 200 may include other components and elements.

According to an embodiment of the present disclosure, the programmable logic device 200 may be configured with a program file (configuration file) in the format of a configuration bit stream. By configuring the programmable logic device 200 with the program file, programmable resources on the target device are physically transformed to implement a system to support hardware acceleration. The programmable resources may include components such as programmable logic blocks and digital signal processor blocks that may be used to implement logic functions. The programmable resources may also include programmable routing that connects the logic functions, programmable clocks that clock the components, a power network that provide power to the components, and other resources on the programmable logic device 200.

The program file in the configuration may be used to configure the programmable logic device 200 using various programming technologies. For instance, the programmable logic device may utilize static random access memory (SRAM), flash, or antifuse-based programming technology to program the programmable resources. The SRAM-based programming technology uses static memory cells which are divided throughout the programmable logic device to configure routing interconnect which are steered by small multiplexers, and to configure logic blocks to implement logic functions. Similarly, flash-based programming technology uses floating-gate transistors in flash memory for configuration storage. Antifuse-based programming technology requires burning of antifuses to program resources. The antifuse-based programming technology allows for programming only once and programmable logic devices utilizing antifuse-based programming cannot be reprogrammed.

Referring back to FIG. 1, a plurality of program files in the format of configuration bit streams may reside in the data storage 172 of the accelerator unit 170. One or more of the program files may be selected to configure and reconfigure the programmable logic device 171 at an appropriate time as directed by the accelerator unit driver 122 in order to allow the programmable logic device 171 to support the functionality and performance of hardware acceleration, and to reduce power consumption during idle states.

Programmable logic device based accelerators, such as accelerator unit 170, cause a computer system to consume additional power, even when the accelerator unit 170 is idle. The additional power consumed raises a total cost of ownership for the computer system, which is undesirable. The accelerator unit driver 122 works together with the accelerator unit 170 to reduce consumption during idle states by leveraging the configurable qualities of the programmable logic device 171. According to an embodiment of the present disclosure, partial reconfiguration is used to switch between different configurations of a programmable logic device. By configuring the programmable logic device 171 to a low power state when the accelerator unit 170 is idle, and a fully operational state when the accelerator unit 170 is active, significant savings in power consumption can be achieved.

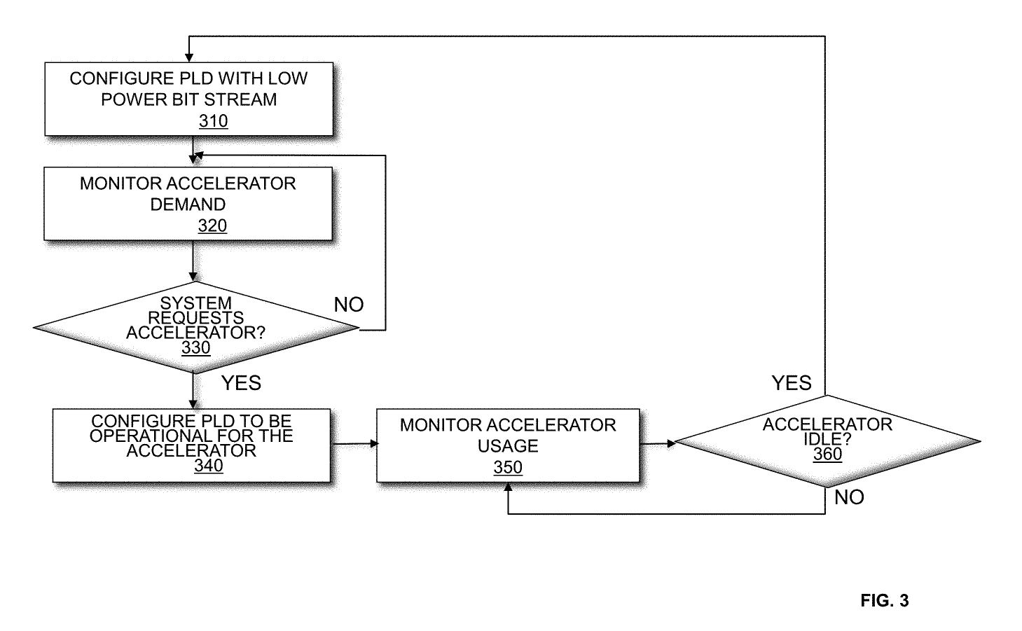

FIG. 3 is a flow chart illustrating a method for managing power on an accelerator unit according to an exemplary embodiment of the present disclosure. The procedures described in FIG. 3 may be performed by the accelerator unit driver 122 shown in FIG. 1. At 310, a programmable logic device on an accelerator unit is configured with a low power bit stream. According to an embodiment of the present disclosure, the low power bit stream is loaded onto the programmable logic device from a data storage, and the low power bit stream configures the programmable logic device to be in a low power state. In the low power state, power to the clocks may be turned off, unused transceivers may be disabled, power to some sections or all sections of the programmable logic device may be turned off, and/or components controlled by the programmable logic device may be put in a low power mode or have their power turned off. It should be appreciated that other power saving measures may be implemented in the low power state.

At 320, the demand for the accelerator unit is monitored. According to an embodiment of the present disclosure, the demand for the accelerator unit is monitored by identifying a request for hardware acceleration made by an application run on a computer system. The demand for the accelerator unit may also be monitored by monitoring an activity of the application run on the computer system to determine whether it requires a processing supported by the accelerator unit.

At 330, if it is determined that the system requires hardware acceleration from the demand monitored, control proceeds to 340. If it is determined that the system does not require hardware acceleration from the demand monitored, control returns to 320 and continues to monitor demand for the accelerator unit.

At 340, the program logic device on the accelerator is configured to be in a fully operational state to support the request for hardware acceleration. According to an embodiment of the present disclosure, a fully operational bit stream is loaded onto the programmable logic device from the data storage, and the fully operational bit stream configures the programmable logic device to be in a fully operational state. In the fully operational state, power to the clocks are turned on, required transceivers are enabled, power to required sections of the programmable logic device are turned on, and/or components controlled by the programmable logic device are put in operational mode or have their power turned on.

At 350, usage of the accelerator unit is monitored to determine whether the accelerator unit is in an idle state. According to an embodiment of the present disclosure, the usage of the accelerator unit may be monitored by identifying whether the request for hardware acceleration continues to be active. When the request for hardware acceleration is not active, a determination may be made that the accelerator unit is in an idle state. It should be appreciated that usage of the accelerator unit may also be monitored by determining whether the power consumption of the accelerator unit exceeds a predetermined threshold value. When the power consumption of the accelerator unit does not exceed the predetermined value, a determination may be made that the accelerator unit is in an idle state. Usage of the accelerator unit may also be monitored by monitoring instructions generated by the operating system of the computer system indicating that the accelerator unit is idle or should be put in an idle state.

At 360, if it is determined that the accelerator unit is in an idle state, control proceeds to 310. If it is determined that the accelerator unit is not in an idle state, control returns to 350 to monitor accelerator unit usage.

According to an embodiment of the present disclosure, the programmable logic device is configured with a first program file in a first configuration bit stream at 310. The first program file includes a detailed design of an hardware accelerator system in a low power state. At a later time, procedure 340 is performed to configure (reconfigure) the programmable logic device with a second program file in a second configuration bit stream to put the hardware accelerator system in a fully operational state. In this embodiment, both the first program file and the second program file include details of a synthesized, placed, and routed hardware accelerator system, and both the first program file and the second program file are similar in size.

According to an alternate embodiment of the present disclosure, the procedures performed in FIG. 3 may be performed after a programmable logic device has been initially configured with a first program file in a first configuration bit stream. The first program file includes a detailed design of an hardware accelerator system. After the programmable logic device has been configured to implement the hardware accelerator system, procedure 310 is performed to further configure the programmable logic device with a second program file in a second configuration bit stream to put the hardware accelerator system in a low power state. At a later time, procedure 340 is performed to further configure (reconfigure) the programmable logic device with a third program file in a third configuration bit stream to put the hardware accelerator system in a fully operational state. In this embodiment, the first program file is a file that includes details of a synthesized, placed, and routed hardware accelerator system. The second program file and the third program file are smaller in size compared to the first program file, as the second program file and the third program file include modifications to the first program file to put the hardware accelerator system into either a low power state or a fully operational state.

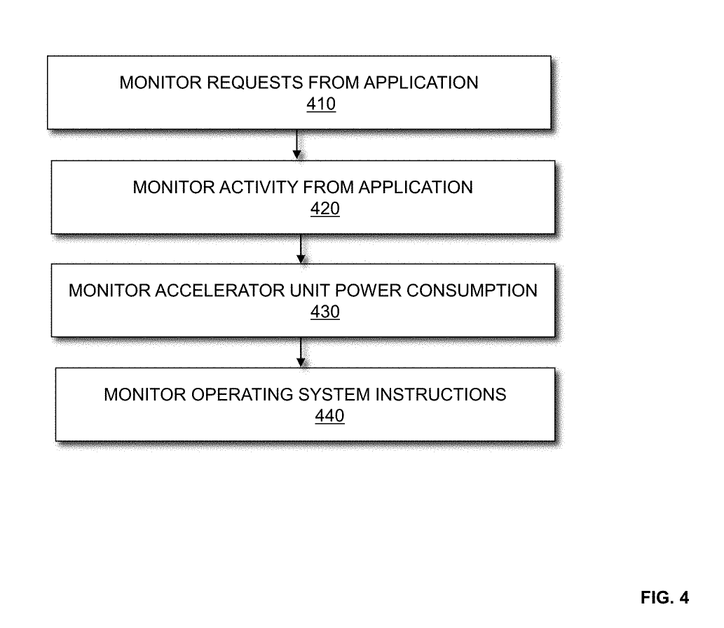

FIG. 4 is a flow chart illustrating a method for monitoring demand and/or usage of an accelerator unit according to an exemplary embodiment of the present disclosure. The procedures described in FIG. 4 may be used in part or in whole to implement procedures 320 and/or 350 shown in FIG. 3. At 410, a request for hardware acceleration made by an application running on a computer system is monitored for. If a request for hardware acceleration made by an application miming on the computer system is identified or is active, control determines that there is demand for the accelerator unit and that usage of the accelerator unit should continue and the programmable logic device in the accelerator unit should be in a fully operational state.

At 420, an application run on a computer system is monitored to determine whether the application's activity requires processing and whether the accelerator unit supports the activity that requires processing. If the application is determined to be engaged in an activity that requires processing supported by the accelerator unit, control determines that there is demand for the accelerator unit and that usage of the accelerator unit should continue and the programmable logic device in the accelerator unit should be in a fully operational state.

At 430, power consumption of the accelerator unit is monitored. If the power consumption of the accelerator unit exceeds a predetermined threshold value, control determines that there is demand for the accelerator unit and that usage of the accelerator unit should continue and the programmable logic device in the accelerator unit should be in a fully operational state.

At 440, instructions generated by an operating system of a computer system are also monitored to determine whether the accelerator unit should be in a fully operational state or an idle state. It should be appreciated that the operating system may issue a sleep command that causes the accelerator unit to enter and stay in a low power state. The operating system may issue a wake command that causes the accelerator unit to enter and stay in a fully operational state to receive work. The operating system may issue a throttle command that causes the accelerator unit to automatically reduce an amount of time the accelerator unit is available or in the fully operational state. This may be achieved by using a software or hardware timer.

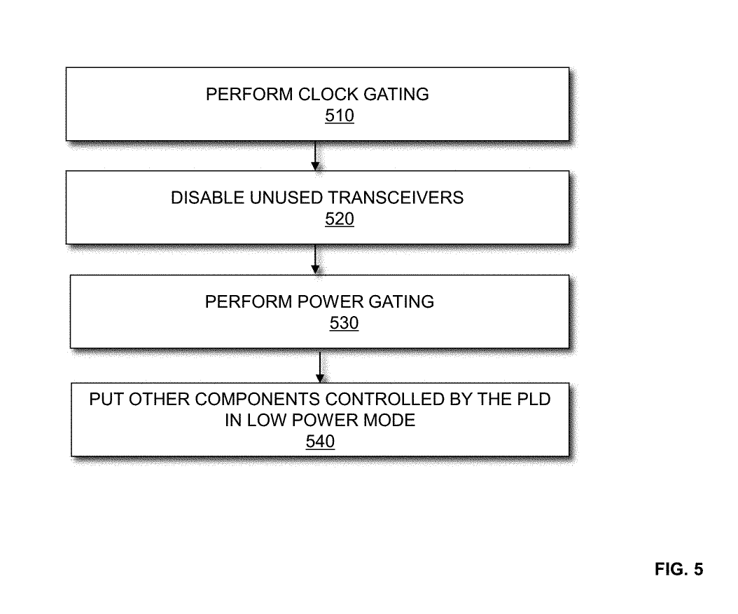

FIG. 5 is a flow chart illustrating a method for managing idle power of a programmable logic device according to an exemplary embodiment of the present disclosure. The procedures described in FIG. 5 may be performed by configuring a programmable logic device on an accelerator unit with a low power bit stream to put the accelerator unit in a low power state. At 510, clock gating is performed by turning off the clocks on the programmable logic device. According to an embodiment of the present disclosure, clock gating circuitry in the programmable logic device is set to switch off the clock. It should be appreciated that some set of clocks will remain on in order to drive components in the programmable logic device needed to maintain connection to the system.

At 520, unused transceivers on the programmable logic device are disabled.

At 530, power gating is performed by shutting off power to one or more sections of the programmable logic. According to an embodiment of the present disclosure, power to the entire programmable logic device may be shut off, except for components in the programmable logic device required to maintain a connection to the system.

At 540, components in the accelerator unit controlled by the programmable logic device are put in a low power mode. According to an embodiment of the present disclosure, a memory on the accelerator unit may be put in low power mode by the programmable logic device. It should be appreciated that other components on the accelerator unit may also be put in low power mode. For example, input or output components connected to the accelerator unit, such as network interfaces, may be put in a low power mode. It should also be appreciated that other power saving procedures may be performed. For example, components connected to but not residing on the accelerator unit may be put in low power mode. These may include cameras and radio transmitters and receivers.

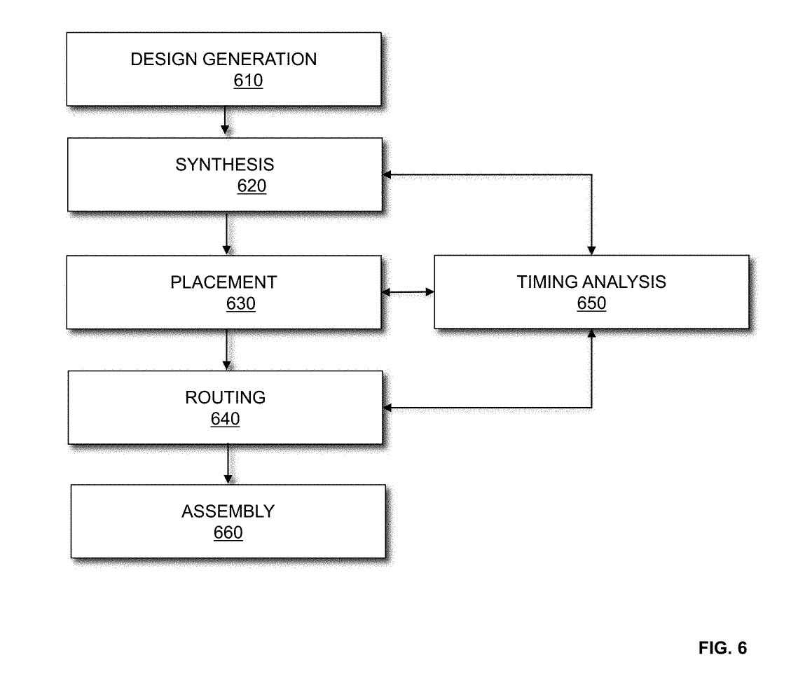

FIG. 6 is a flow chart illustrating a method for generating program files for configuring a programmable logic device based accelerator system according to an exemplary embodiment of the present disclosure. The procedures described in FIG. 6 may collectively be referred to as “compilation” of a design. The target device which the described procedures are performed on may be a programmable logic device such as a field programmable gate array (FPGA) or other device whose functionality is described by a hardware description language (HDL). At 610, a design for the system is generated. The system may be a hardware accelerator system for an accelerator unit. According to an embodiment of the present disclosure, the design is generated in response to input provided by a user. In this embodiment, the user may input a register-transfer-level (RTL) description of the system, select and connect logic from a design library, or utilize other design input options. Alternatively, the input provided by the user may be a computer language description of the system. In this embodiment, a high-level compilation of the computer language description of the system is performed. The design for the system generated may be in HDL.

At 620, the system is synthesized and a netlist is generated. Synthesis includes generating a logic design of the system to be implemented by the target device. According to an embodiment of the present disclosure, synthesis generates an optimized logical representation of the system from an HDL design definition. Synthesis also includes mapping the optimized logic design (technology mapping). Mapping includes determining how to implement logic gates and logic elements in the optimized logic representation with specific resources on the target device such as logic elements and functional blocks. According to an embodiment of the present disclosure, a netlist is generated from mapping. This netlist may be an optimized technology-mapped netlist generated from the HDL.

According to an embodiment of the present disclosure, a plurality of versions of the design may be generated during synthesis. For example, a first version of the design may be a version of the hardware accelerator system to operate in a low power state, and a second version of the design may be a version of the hardware accelerator system to operate in a fully operational state. Clock gating circuitry, power gating circuitry, and other power saving circuitry may be added to the hardware accelerator system during synthesis to allow for the hardware accelerator system to consume less power when operating in the low power state. In one embodiment, synthesis generates a version of the hardware accelerator system to operate in a low power state that includes a proper subset of components from the original design in order to reduce power consumption requirements. When a plurality of versions of the design are generated during synthesis, the plurality of versions are subsequently placed, routed, timing analyzed, and assembled.

At 630, the system is placed. According to an embodiment of the present disclosure, placement involves placing the mapped logical system design on the target device. Placement works on the technology-mapped netlist to produce a placement for each of the logic elements and functional blocks. According to an embodiment of the present disclosure, placement includes fitting the system on the target device by determining which resources on the target device are to be used to implement the logic elements and functional blocks identified during synthesis. Placement may include clustering which involves grouping logic elements together to form the logic clusters present on the target device. According to an embodiment of the present disclosure, clustering is performed at an early stage of placement and occurs after synthesis during the placement preparation stage. Placement may also minimize the distance between interconnected resources to meet timing constraints of the timing netlist.

At 640, the placed design is routed. During routing, routing resources on the target device are allocated to provide interconnections between logic gates, logic elements, and other components on the target device. According to an embodiment of the present disclosure, routing aims to reduce the amount of wiring used to connect components in the placed logic design. Routability may include performing fanout splitting, logic duplication, logical rewiring, or other procedures. It should be appreciated that one or more of the procedures may be performed on the placed logic design. Timing optimization may also be performed during routing to allocate routing resources to meet the timing constraints of the timing netlist.

At 650, timing analysis is performed on the system designed. According to an embodiment of the present disclosure, the timing analysis determines whether timing constraints of the system are satisfied. As part of timing analysis, slack analysis may be performed. It should be appreciated that the timing analysis may be performed during and/or after each of the synthesis 620, placement 630, and routing procedures 640 to guide compiler optimizations.

At 660, an assembly procedure is performed. The assembly procedure involves creating a program file that includes information determined by the procedures described at 610, 620, 630, and 640. The program file may be a bit stream that may be used to program a target device. According to an embodiment of the present disclosure, the procedures illustrated in FIG. 6 may be performed by an EDA tool executed on a first computer system. The program file generated may be transmitted to a second computer system to allow the design of the system to be further processed. The program file may be transmitted from either the first or second computer system onto the target device and used to program the target device according to the system design. It should be appreciated that the design of the system may also be output in other forms such as on a display device or other medium. The target device may be programmed with the program file. By programming the target with the program file, components (programmable resources) on the target device are physically transformed to implement the system.

It should be appreciated that when a plurality of versions of a design is generated for a system, a program file may be generated for each of the versions. In an embodiment where the system is desired to be put in particular state, the program file may be used to reconfigure the system to the desired state. The reconfiguration may involve a full or partial reconfiguration of the system.

FIGS. 3-6 are flow charts that illustrate embodiments of the present disclosure. The procedures described in these figures may be performed by an accelerator unit driver, a configuration bit stream, or an EDA tool implemented by a computer system. Some of the techniques illustrated may be performed sequentially, in parallel or in an order other than that which is described and that the procedures described may be repeated. It is appreciated that not all of the techniques described are required to be performed, that additional techniques may be added, and that some of the illustrated techniques may be substituted with other techniques.

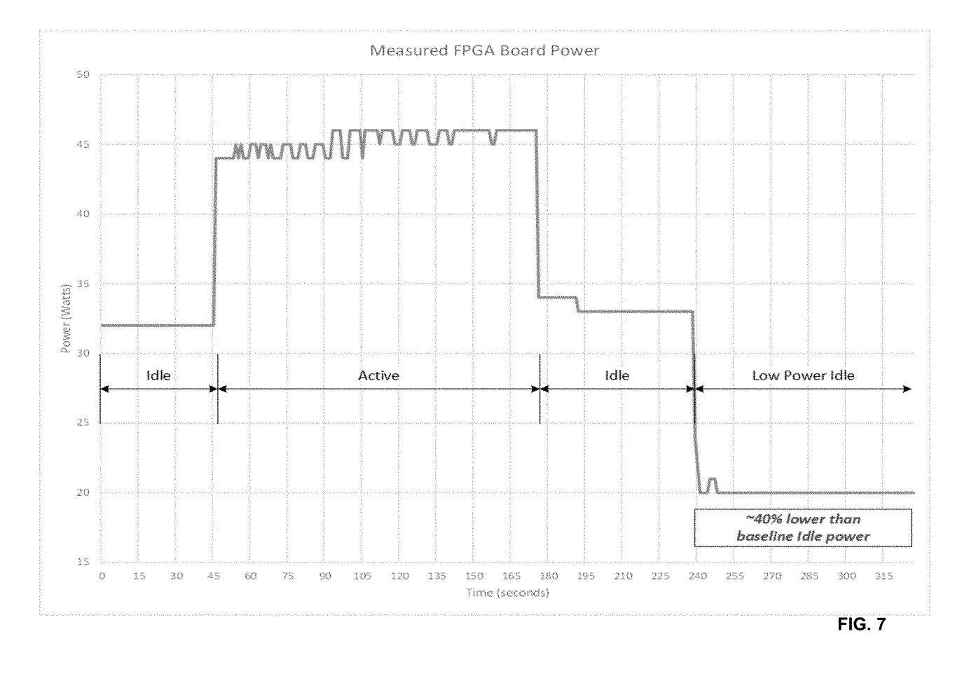

FIG. 7 illustrates the power requirement of an accelerator unit during various operational stages when utilizing the power management methodology according to an exemplary embodiment of the present disclosure. In this embodiment, an accelerator unit is implemented on a board and is referred to as an FPGA Board. Initially, the programmable logic device on the accelerator unit is configured with a first program file in a first bit stream to put the accelerator unit in a fully operational state. From time 0 to 45 seconds, the accelerator unit is in an idle state. As illustrated, during this idle state, the accelerator unit is consuming approximately 32 Watts of power while configured in the fully operational state.

From time 45 seconds to 180 seconds, the accelerator unit is in an active state. As illustrated, during this active state, the accelerator unit is consuming approximately 45 watts of power while configured in the fully operational state.

From time 180 to 240 seconds, the accelerator unit returns to an idle state. As illustrated, during this idle state, the accelerator unit is consuming approximately 33 Watts of power while configured in the fully operational state.

At time 240 seconds, the programmable logic device on the accelerator unit is configured with a second program file in a second bit stream to put the accelerator unit in a low power state. From time 240 seconds on, while in this idle state, the accelerator unit is consuming approximately 20 Watts of power while configured in the low power state. As illustrated in this example, idle power is reduced by approximately 40% when a programmable logic device is configured with a program file in a bit stream that puts the accelerator unit in a low power state.

It should be appreciated that embodiments of the present disclosure may be provided as a computer program product, or software, that may include a computer-readable or machine-readable medium having instructions. The instructions on the computer-readable or machine-readable medium may be used to program a computer system or other electronic device. The machine-readable medium may include, but is not limited to, floppy diskettes, optical disks, CD-ROMs, and magneto-optical disks or other type of media/machine-readable medium suitable for storing electronic instructions. The techniques described herein are not limited to any particular software configuration. They may find applicability in any computing or processing environment. The terms “computer-readable medium” or “machine-readable medium” used herein shall include any medium that is capable of storing or encoding a sequence of instructions for execution by the computer and that cause the computer to perform any one of the methods described herein. Furthermore, it is common in the art to speak of software, in one form or another (e.g., program, procedure, process, application, module, unit, logic, and so on) as taking an action or causing a result. Such expressions are merely a shorthand way of stating that the execution of the software by a processing system causes the processor to perform an action to produce a result.

The following examples pertain to further embodiments. In one embodiment, a method for managing power on a programmable logic device (PLD) based accelerator unit in a computer system, includes determining when the PLD based accelerator unit is in an idle state. A PLD in the PLD based accelerator unit is reconfigured from a fully operational state to a low power state in response to determining the accelerator unit is in the idle state.

In a further embodiment, the method wherein reconfiguring the PLD includes loading a bit stream onto the PLD, and programming the PLD with the bit stream to physically transform components on the PLD to support operation in the low power state.

In a further embodiment, the method wherein in the low power state, clocks on the PLD are turned off.

In a further embodiment, the method wherein in the low power state, unused transceivers on the PLD are disabled.

In a further embodiment, the method wherein in the low power state, power is turned off to a portion of the PLD.

In a further embodiment, the method wherein in the low power state, a memory controlled by the PLD is placed in low power mode.

In a further embodiment, the method wherein determining when the PLD based accelerator unit is in the idle state is achieved by monitoring requests to use the PLD based accelerator made by an application running on the computer system.

In a further embodiment, the method wherein determining when the PLD based accelerator unit is in the idle state is achieved by monitoring power usage of the PLD based accelerator unit.

In a further embodiment, the method wherein determining when the PLD based accelerator unit is in the idle state is achieved by processing information from an operating system of the computer system.

In a further embodiment, the method further comprising reconfiguring the PLD back to the fully operational state in response to determining that the PLD based accelerator unit is required to support an application running on the computer system.

In a further embodiment, a method for managing power on a programmable logic device (PLD) based accelerator unit in a computer system includes configuring a PLD to a low power state, and reconfiguring the PLD from the low power state to a fully operational state in response to determining that an application running on the computer system is requesting access to the PLD based accelerator unit.

In a further embodiment, the method further comprising determining whether the PLD based accelerator unit is in an idle state, and reconfiguring the PLD to the low power state from the fully operational state to the low power state in response to determining that the PLD based accelerator unit is in the idle state.

In a further embodiment, the method wherein configuring the PLD to the low power state comprises loading a bit stream onto the PLD from data storage on the PLD based accelerator unit, and programming the PLD with the bit stream to physically transform components on the PLD.

In a further embodiment, the method wherein in the low power state, clocks on the PLD are turned off.

In a further embodiment, the method wherein in the low power state, unused transceivers on the PLD are disabled.

In a further embodiment, the method wherein in the low power state, power is turned off to a portion of the PLD.

In a further embodiment, the method wherein in the low power state, memory is placed in low power mode.

In a further embodiment, the method wherein determining whether the PLD based accelerator unit is in the idle state is achieved by monitoring requests made by an application running on the computer system.

In a further embodiment, the method wherein determining whether the PLD based accelerator unit is in the idle state is achieved by monitoring power usage of the PLD based accelerator unit.

In a further embodiment, the method wherein determining whether the PLD based accelerator unit is in the idle state is achieved by processing information from an operating system of a computer system that utilizes the PLD.

In a further embodiment, a non-transitory computer readable medium including a sequence of instructions stored thereon for causing a computer to execute a method for designing a hardware accelerator system on a programmable logic device (PLD) that includes, receiving a design for the hardware accelerator system, synthesizing a first version of the hardware accelerator system to operate at a low power state, synthesizing a second version of the hardware accelerator system to operate at a fully operational state, placing and routing the first version and the second version of the hardware accelerator system on the PLD, generating a first program file that describes the first version of the hardware accelerator system and a second program file that describes the second version of the hardware accelerator system, and configuring the programmable logic device with the first program file to physically transform components on the PLD to implement the hardware accelerator system to operate at the low power state.

In a further embodiment, the non-transitory computer readable medium wherein synthesizing the first version of the hardware accelerator system to operate at the low power state comprises adding clock gating circuitry to turn off clocks to the hardware accelerator system.

In a further embodiment, the non-transitory computer readable medium wherein synthesizing the first version of the hardware accelerator system to operate at the low power state comprises adding power gating circuitry to turn off power to portions of the hardware accelerator system.

In a further embodiment, the non-transitory computer readable medium further comprising reconfiguring the PLD with the second program file to physically transform the components on the PLD to implement the hardware accelerator system to operate at the fully operational state in response to determining that an application running on a computer system is requesting access to the hardware accelerator system.

In the foregoing specification, embodiments of the disclosure have been described with reference to specific exemplary embodiments thereof. It will, however, be evident that various modifications and changes may be made thereto without departing from the broader spirit and scope of the embodiments of the disclosure. The specification and drawings are, accordingly, to be regarded in an illustrative rather than restrictive sense.

What is claimed is:

1. A method for managing power on a programmable logic device (PLD) based accelerator unit in a computer system, comprising:
determining when the PLD based accelerator unit is in an idle state; and
reconfiguring a PLD in the PLD based accelerator unit from a fully operational state to a low power state in response to determining the accelerator unit is in the idle state.

2. The method of claim 1, wherein reconfiguring the PLD comprises:
loading a bit stream onto the PLD; and
programming the PLD with the bit stream to physically transform components on the PLD to support operation in the low power state.

3. The method of claim 2, wherein in the low power state, clocks on the PLD are turned off.

4. The method of claim 2, wherein in the low power state, unused transceivers on the PLD are disabled.

5. The method of claim 2, wherein in the low power state, power is turned off to a portion of the PLD.

6. The method of claim 2, wherein in the low power state, a memory controlled by the PLD is placed in low power mode.

7. The method of claim 1, wherein determining when the PLD based accelerator unit is in the idle state is achieved by monitoring requests to use the PLD based accelerator made by an application running on the computer system.

8. The method of claim 1, wherein determining when the PLD based accelerator unit is in the idle state is achieved by monitoring power usage of the PLD based accelerator unit.

9. The method of claim 1, wherein determining when the PLD based accelerator unit is in the idle state is achieved by processing information from an operating system of the computer system.

10. The method of claim 1 further comprising reconfiguring the PLD back to the fully operational state in response to determining that the PLD based accelerator unit is required to support an application running on the computer system.

11. A method for managing power on a programmable logic device (PLD) based accelerator unit in a computer system, comprising:
configuring a PLD to a low power state; and
reconfiguring the PLD from the low power state to a fully operational state in response to determining that an application running on the computer system is requesting access to the PLD based accelerator unit.

12. The method of claim 11 further comprising:
determining whether the PLD based accelerator unit is in an idle state; and
reconfiguring the PLD to the low power state from the fully operational state to the low power state in response to determining that the PLD based accelerator unit is in the idle state.

13. The method of claim 11, wherein configuring the PLD to the low power state comprises:
loading a bit stream onto the PLD from data storage on the PLD based accelerator unit; and
programming the PLD with the bit stream to physically transform components on the PLD.

14. The method of claim 11, wherein in the low power state, clocks on the PLD are turned off.

15. The method of claim 11, wherein in the low power state, unused transceivers on the PLD are disabled.

16. The method of claim 11, wherein in the low power state, power is turned off to a portion of the PLD.

17. The method of claim 11, wherein in the low power state, memory is placed in low power mode.

18. The method of claim 12, wherein determining whether the PLD based accelerator unit is in the idle state is achieved by monitoring requests made by an application running on the computer system.

19. The method of claim 12, wherein determining whether the PLD based accelerator unit is in the idle state is achieved by monitoring power usage of the PLD based accelerator unit.

20. The method of claim 12, wherein determining whether the PLD based accelerator unit is in the idle state is achieved by processing information from an operating system of a computer system that utilizes the PLD.

21. A non-transitory computer readable medium including a sequence of instructions stored thereon for causing a computer to execute a method for designing a hardware accelerator system on a programmable logic device (PLD), comprising:
receiving a design for the hardware accelerator system;
synthesizing a first version of the hardware accelerator system to operate at a low power state;
synthesizing a second version of the hardware accelerator system to operate at a fully operational state;
placing and routing the first version and the second version of the hardware accelerator system on the PLD;
generating a first program file that describes the first version of the hardware accelerator system and a second program file that describes the second version of the hardware accelerator system; and
configuring the programmable logic device with the first program file to physically transform components on the PLD to implement the hardware accelerator system to operate at the low power state.

22. The non-transitory computer readable medium of claim 21, wherein synthesizing the first version of the hardware accelerator system to operate at the low power state comprises adding clock gating circuitry to turn off clocks to the hardware accelerator system.

23. The non-transitory computer readable medium of claim 21, wherein synthesizing the first version of the hardware accelerator system to operate at the low power state comprises adding power gating circuitry to turn off power to portions of the hardware accelerator system.

24. The non-transitory computer readable medium of claim 21 further comprising reconfiguring the PLD with the second program file to physically transform the components on the PLD to implement the hardware accelerator system to operate at the fully operational state in response to determining that an application running on a computer system is requesting access to the hardware accelerator system.
